(19) United States
(12) Patent Application Publication
(10) Pub. No.: US 2011/0109364 A1
(43) Pub. Date: May 12, 2011

(54) INPUT CIRCUIT

(76) Inventors: Taro Yamasaki, Chiba-shi (JP); Fumiyasu Utsunomiya, Chiba-shi (JP)

(21) Appl. No.: 12/943,697

(22) Filed: Nov. 10, 2010

(30) Foreign Application Priority Data
Nov. 11, 2009 (JP) 2009-258413

(51) Int. Cl. H03K 3/00

(52) U.S. Cl. 327/206

(57) ABSTRACT

Provided is an input circuit having hysteresis characteristics that is capable of operating in a wide range of power supply voltage conditions while suppressing power supply voltage dependence of a hysteresis voltage and a response speed. The input circuit is provided with: a circuit for obtaining a small hysteresis voltage under the condition of low power supply voltage (formed of PMOS transistors (101 to 103) and an inverter (501)); and a circuit for obtaining a large hysteresis voltage under the condition of low power supply voltage (formed of PMOS transistors (101 and 104) and the inverter (501)).

### RELATED APPLICATIONS

This application claims priority under 35 U.S.C. §119 to Japanese Patent Application No. 2009-258413 filed on Nov. 11, 2009, the entire content of which is hereby incorporated by reference.

### BACKGROUND OF THE INVENTION

1. Field of the Invention

The present invention relates to an input circuit for a semiconductor integrated circuit, and more particularly, to an input circuit with hysteresis having improved power supply voltage characteristics.

2. Description of the Related Art

A conventional input circuit having hysteresis characteristics is described (see Japanese Patent Application Laid-open No. Hei 10-229331).

FIG. 14 is a circuit diagram illustrating the conventional input circuit with hysteresis. If an input voltage VIN of an input terminal 401 shifts from High to Low, a PMOS transistor 803 for providing hysteresis is turned OFF. Accordingly, a threshold voltage of an inverter circuit is determined by a ratio of ON-state resistances between a PMOS transistor 801 and an NMOS transistor 901. If the input voltage VIN shifts from Low to High, the PMOS transistor 803 for providing hysteresis is turned ON. Accordingly, the ON-state resistance of the PMOS transistor 801 is smaller than that of the NMOS transistor 901 because of the turned-ON PMOS transistor 803. Therefore, the threshold voltage of the inverter circuit is determined by a ratio of ON-state resistances between the two PMOS transistors 801 and 803 and the NMOS transistor 901. Consequently, the threshold of the inverter circuit is increased when the input voltage VIN shifts from Low to High as compared with the shift of the input voltage VIN from High to Low. In other words, the threshold of the inverter circuit has hysteresis.

FIG. 15 is a circuit diagram illustrating another example of the conventional input circuit with hysteresis. If the input voltage VIN shifts from Low to High, a switching PMOS transistor 805 is turned OFF in conjunction with a PMOS transistor 804 being turned ON. As compared with the circuit of FIG. 14, the circuit of FIG. 15 is therefore capable of reducing current consumption during switching.

In the conventional technologies, however, such hysteresis voltage and response speed suffer from the power supply voltage dependence as described below.

First, the input circuit with hysteresis of FIG. 15 is described. If the input voltage YIN shifts from Low to High under the condition of low power supply voltage, the input voltage VIN approaches the circuit threshold voltage from Low. Then, each gate-source voltage of the PMOS transistors 801 and 804 falls below its transistor threshold. At this time, the PMOS transistors 801 and 804 are each biased in the weak inversion region and accordingly have a larger ON-state resistance than that at a high power supply voltage. For that reason, a small hysteresis voltage is obtained under the condition of low power supply voltage. On the contrary, if the ratio of the ON-state resistance of the NMOS transistor 901 to the ON-state resistance of the PMOS transistor 801 is increased so as to obtain a large hysteresis voltage at the low power supply voltage, the circuit threshold increases at a high power supply voltage to make it impossible for the input circuit to receive an input signal with a small swing width. In addition, the increase in ON-state resistance of the NMOS transistor 901 is accompanied by the reduction in response speed at the low power supply voltage.

Next, the input circuit with hysteresis of FIG. 14 is described. If the input voltage YIN shifts from Low to High under the condition of low power supply voltage, the gate-source voltage of the PMOS transistor 801 falls below its threshold so that the PMOS transistor 801 is biased in the weak inversion region to have a larger ON-state resistance than that at a high power supply voltage. However, a gate-source voltage of the PMOS transistor 803 remains equal to the power supply voltage until an output terminal 402 of the input circuit is inverted to High. Accordingly, when the input voltage VIN shifts from Low to High, the ON-state resistance of the PMOS transistor 803 is hardly dependent on the power supply voltage as long as the power supply voltage is equal to or higher than its transistor threshold. Then, under the condition of low power supply voltage, an apparent influence of current drivability of the PMOS transistor 803 is so large to reduce the ON-state resistances of the PMOS transistors. This way, a large hysteresis voltage is obtained under the condition of low power supply voltage. As described above, a high circuit threshold makes it impossible for the input circuit to receive an input signal with a small swing width. If design is made such that the circuit threshold is prevented from being too high under the condition of low power supply voltage, a small hysteresis voltage is obtained under the condition of power supply voltage in which the PMOS transistor 801 operates in the strong inversion region with the voltage thereof being around the circuit threshold. In addition, under the condition of low power supply voltage, the current drivability of the NMOS transistor 901 is lower than those of the PMOS transistors, with the result that the response speed reduces under the condition of low power supply voltage.

### SUMMARY OF THE INVENTION

The present invention has been made in view of the above-mentioned problems, and therefore provides an input circuit with hysteresis that is capable of operating in a wide range of power supply voltage conditions while suppressing power supply voltage dependence of a hysteresis voltage and a response speed.

In order to solve the conventional problems, an input circuit with hysteresis according to the present invention has the following configuration.

An input circuit includes: an input terminal for receiving an input voltage; an output terminal for outputting an output signal to be determined based on the input voltage; a first PMOS transistor for charging a first node when the input voltage is Low; a first NMOS transistor for discharging the first node when the input voltage is High; a second PMOS transistor for charging the first node when the input voltage is Low; first interrupting means for interrupting a charge path of the second PMOS transistor to the first node when a voltage of the first node is Low; and a third PMOS transistor for charging the first node when the voltage of the first node is High.

Further, an input circuit includes: an input terminal for receiving an input voltage; an output terminal for outputting an output signal to be determined based on the input voltage; a first PMOS transistor for charging a first node when the input voltage is Low; a first NMOS transistor for discharging the first node when the input voltage is High; a second NMOS transistor for discharging the first node when the input voltage is High; second interrupting means for interrupting a discharge path of the second NMOS transistor from the first node when a voltage of the first node is High; and a third NMOS transistor for discharging the first node when the voltage of the first node is Low.

The present invention is capable of ensuring a large hysteresis voltage in a wide range of power supply voltage conditions without using a logic circuit, an operational amplifier circuit, or the like. Besides, a ratio of an ON-state resistance of an NMOS transistor to an ON-state resistance of a PMOS transistor may be reduced as compared with the conventional technologies, to thereby prevent a response speed from reducing during low power supply voltage operation. Further, as compared with the conventional circuits, hysteresis characteristics to be obtained are less dependent on the power supply voltage, and hence it is possible to make design without increasing a circuit scale.

As described above, the input circuit according to the present invention provides an effect of, as compared with the conventional technologies, suppressing the power supply voltage dependence of the hysteresis voltage and the response speed without increasing the circuit scale.

### BRIEF DESCRIPTION OF THE DRAWINGS

In the accompanying drawing:

FIG. 1 is a circuit diagram illustrating an input circuit according to a first embodiment of the present invention;

FIG. 2 is a circuit diagram illustrating an input circuit according to a second embodiment of the present invention;

FIG. 3 is a circuit diagram illustrating an input circuit according to a third embodiment of the present invention;

FIG. 4 is a circuit diagram illustrating an input circuit according to a fourth embodiment of the present invention;

FIG. 5 is a circuit diagram illustrating an input circuit according to a fifth embodiment of the present invention;

FIG. 6 is a circuit diagram illustrating an input circuit according to a sixth embodiment of the present invention;

FIG. 7 is a circuit diagram illustrating an input circuit according to a seventh embodiment of the present invention;

FIG. 8 is a circuit diagram illustrating an input circuit according to an eighth embodiment of the present invention;

FIG. 9 is a circuit diagram illustrating a first example of an input circuit according to a ninth embodiment of the present invention;

FIG. 10 is a circuit diagram illustrating a second example of the input circuit according to the ninth embodiment of the present invention;

FIG. 11 is a circuit diagram illustrating a third example of the input circuit according to the ninth embodiment of the present invention;

FIG. 12 is a circuit diagram illustrating a fourth example of the input circuit according to the ninth embodiment of the present invention;

FIG. 13 is a circuit diagram illustrating an input circuit according to a tenth embodiment of the present invention;

FIG. 14 is a circuit diagram illustrating a first example of a conventional input circuit; and

FIG. 15 is a circuit diagram illustrating a second example of the conventional input circuit.

### DETAILED DESCRIPTION OF THE PREFERRED EMBODIMENTS

Now, referring to the accompanying drawings, embodiments of the present invention are described below.

### First Embodiment

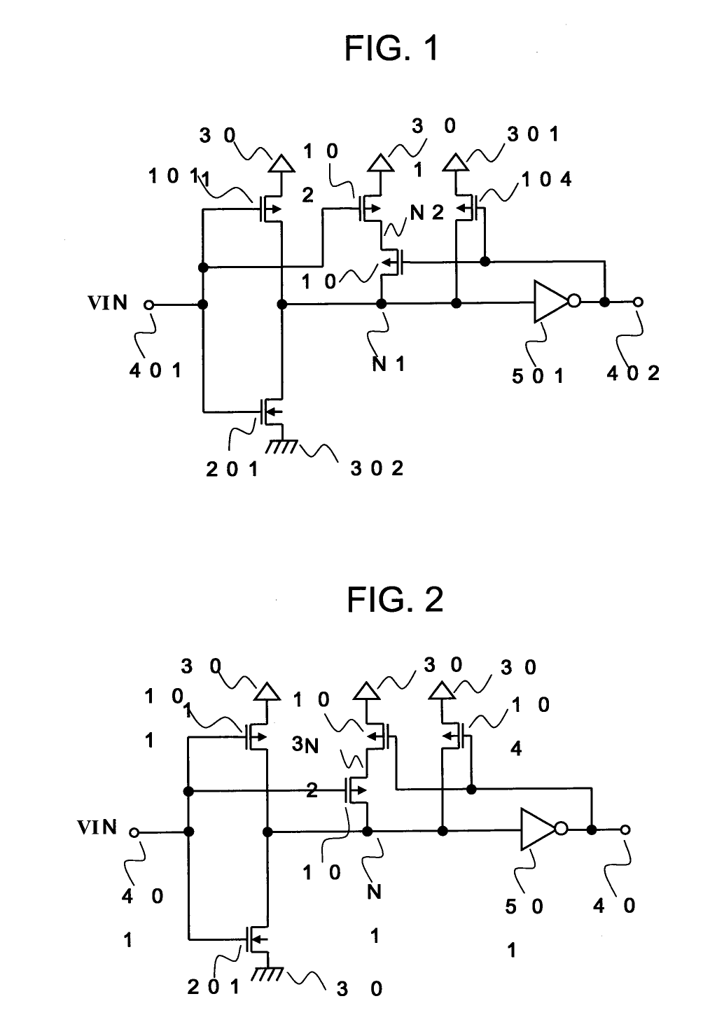

FIG. 1 is an input circuit having hysteresis characteristics according to a first embodiment of the present invention.

The input circuit having hysteresis characteristics according to the first embodiment includes PMOS transistors 101 to 104, an NMOS transistor 201, an inverter 501, a first power source 301 (hereinafter referred to as VDD), a second power source 302 (hereinafter referred to as VSS), the voltage of which is lower than that of the first power source 301, an input terminal 401, and an output terminal 402.

The PMOS transistors 101, 102, and 104 each have a source connected to VDD, while the NMOS transistor 201 has a source connected to VSS. The PMOS transistor 101 and the NMOS transistor 201 each have a gate connected to the input terminal 401 and a drain connected to a node N1. The inverter 501 has an input connected to the node N1 and an output connected to the output terminal 402. The PMOS transistor 102 has a gate connected to the input terminal 401 and a drain connected to a node N2. The PMOS transistor 103 has a gate connected to the output terminal 402, a source connected to the node N2, and a drain connected to the node N1. The PMOS transistor 103 is provided between the node N1 and the node N2 to function as interrupting means. The PMOS transistor 104 has a gate connected to the output terminal 402 and a drain connected to the node N1. The PMOS transistor 101 and the NMOS transistor 201 together form an inverter circuit.

Note that, although not illustrated, the PMOS transistors 101 to 104 each have a back gate connected to VDD or a higher potential than its source potential, while the NMOS transistor 201 has a back gate connected to VSS or a lower potential than its source potential.

Next, an operation of the input circuit having hysteresis characteristics according to the first embodiment is described.

If an input voltage VIN of the input terminal 401 shifts from High to Low, a voltage of the output terminal 402 remains High until the input voltage falls below a threshold of the entire circuit. The PMOS transistors 103 and 104 are accordingly turned OFF. When the input voltage thereafter falls below a threshold of the circuit formed of the PMOS transistor 101 and the NMOS transistor 201, the node N1 shifts to High and the output terminal 402 shifts from High to Low. In other words, the threshold of the entire circuit is determined by the threshold of the circuit formed of the PMOS transistor 101 and the NMOS transistor 201, the value of which is determined by a ratio of ON-state resistances between the PMOS transistor 101 and the NMOS transistor 201.

If the input voltage shifts from Low to High, the voltage of the output terminal 402 remains Low until the input voltage exceeds the threshold of the entire circuit. The PMOS transistors 103 and 104 are accordingly turned ON. Therefore, as compared with the shift of the input from High to Low, the ON-state resistance of the PMOS transistor 101 is small because of the PMOS transistors 102 and 104. This way, the threshold of the entire circuit increases to provide hysteresis to the input circuit.

Here, taking no account of the PMOS transistor 104, consider the power supply voltage dependence of the configuration of the circuit diagram of FIG. 1 including the PMOS transistors 101 to 103, the NMOS transistor 201, and the inverter 501. If the input voltage approaches the threshold voltage from Low at a low power supply voltage, the PMOS transistors 101 and 102 are each biased in the weak inversion region. The ON-state resistances of the PMOS transistors 101 and 102 at this time are larger than those at a high power supply voltage, where the PMOS transistors 101 and 102 each operate in the strong inversion region with the input voltage being around the threshold voltage. Therefore, under the condition of low power supply voltage, a small hysteresis voltage is obtained.

Next, taking no account of the PMOS transistors 102 and 103, consider the power supply voltage dependence of the configuration of the circuit diagram of FIG. 1 including the PMOS transistors 101 and 104, the NMOS transistor 201, and the inverter 501. As described above, under the condition of low power supply voltage, when the input voltage approaches the circuit threshold voltage from Low, the PMOS transistors 101 and 104 are each biased in the weak inversion region to have a larger ON-state resistance than that under the condition of high power supply voltage. On this occasion, a gate-source voltage of the PMOS transistor 104 remains equal to the power supply voltage until the output terminal 402 is inverted to High. Therefore, the ON-state resistance of the PMOS transistor 104 is hardly dependent on the power supply voltage as long as the power supply voltage is equal to or higher than the transistor threshold of the PMOS transistor 104. Further, as the power supply voltage becomes lower, an influence of current drivability of the PMOS transistor 104 becomes larger to reduce the ON-state resistances of the PMOS transistors. Consequently, under the condition of low power supply voltage, a large hysteresis voltage is obtained.

The input circuit according to the first embodiment is provided with two circuits, one of which is formed of the PMOS transistors 101 and 104 and the inverter 501 and enabled under the condition of low power supply voltage to keep a large hysteresis voltage, and the other of which is formed of the PMOS transistors 101 to 103 and the inverter 501 and enabled under the condition of high power supply voltage to keep a large hysteresis voltage as well. This way, the power supply voltage dependence of the hysteresis voltage may be suppressed. There is therefore no need to increase the current drivability of the PMOS transistor 102 at the high power supply voltage, so as to allow the PMOS transistor 102 with low current drivability. Besides, current consumption during switching may be reduced as well. Further, it is possible to further reduce a ratio of the current drivability of the PMOS transistor 102 to that of the NMOS transistor 201, and hence the response speed for input from Low to High is prevented from reducing at the low power supply voltage.

As described above, the input circuit having hysteresis characteristics of the first embodiment is capable of operating in a wide range of power supply voltage conditions while suppressing the power supply voltage dependence of the hysteresis voltage and the response speed. Besides, current consumption during switching may be reduced without increasing a circuit scale.

### Second Embodiment

FIG. 2 is an input circuit having hysteresis characteristics according to a second embodiment of the present invention.

The input circuit having hysteresis characteristics according to the second embodiment includes PMOS transistors 101 to 104, an NMOS transistor 201, an inverter 501, a first power source 301 (hereinafter referred to as VDD), a second power source 302 (hereinafter referred to as VSS), the voltage of which is lower than that of the first power source 301, an input terminal 401, and an output terminal 402. The second embodiment is different from the first embodiment in the following points. The PMOS transistor 102 has a drain connected to a node N1 and a source connected to a node N2. The PMOS transistor 103 as the interrupting means has a drain connected to the node N2 and a source connected to VDD.

Next, an operation of the input circuit having hysteresis characteristics according to the second embodiment is described.

As compared with the first embodiment, the second embodiment has a configuration in which the PMOS transistor 102 and the PMOS transistor 103 switch places with each other. Also in this case, the input circuit operates in the same manner as in the first embodiment to obtain the same effects.

Therefore, the input circuit having hysteresis characteristics according to the second embodiment is capable of operating in a wide range of power supply voltage conditions while suppressing the power supply voltage dependence of the hysteresis voltage and the response speed. Besides, current consumption during switching may be reduced without increasing a circuit scale.

### Third Embodiment

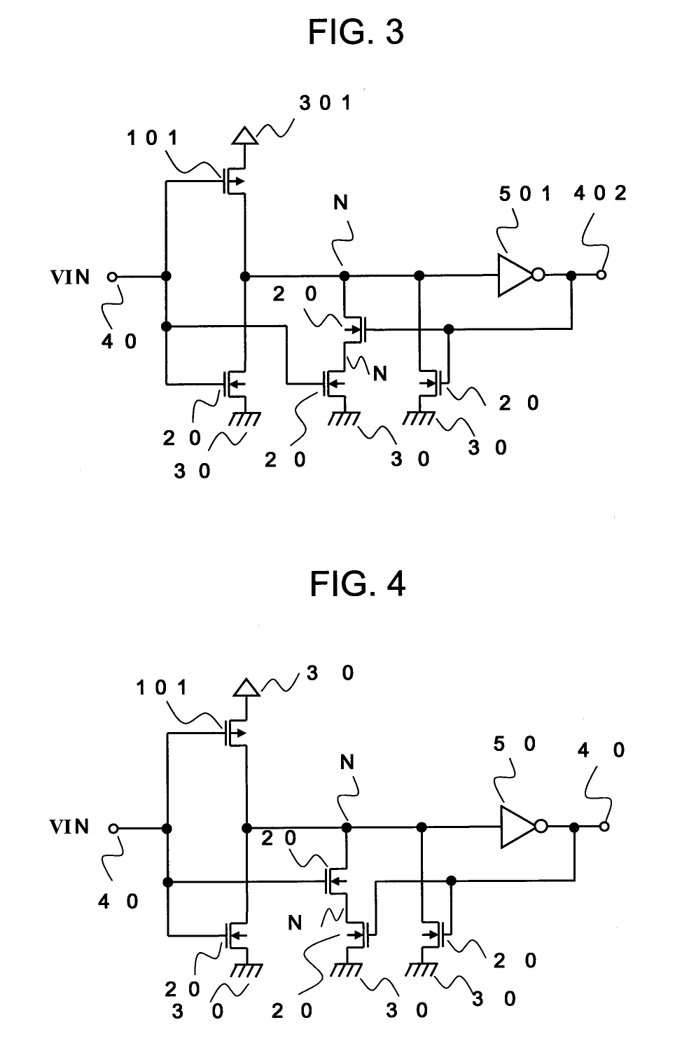

FIG. 3 is an input circuit having hysteresis characteristics according to a third embodiment of the present invention.

The input circuit having hysteresis characteristics according to the third embodiment includes NMOS transistors 201 to 204, a PMOS transistor 101, an inverter 501, a first power source 301 (hereinafter referred to as VDD), a second power source 302 (hereinafter referred to as VSS), the voltage of which is lower than that of the first power source 301, an input terminal 401, and an output terminal 402.

The NMOS transistors 201, 202, and 204 each have a source connected to VSS, while the PMOS transistor 101 has a source connected to VDD. The PMOS transistor 101 and the NMOS transistor 201 each have a gate connected to the input terminal 401 and a drain connected to a node N1. The inverter 501 has an input connected to the node N1 and an output connected to the output terminal 402. The NMOS transistor 202 has a gate connected to the input terminal 401 and a drain connected to a node N3. The NMOS transistor 203 has a gate connected to the output terminal 402, a source connected to the node N3, and a drain connected to the node N1. The NMOS transistor 203 is provided between the node N1 and the node N3 to function as interrupting means. The NMOS transistor 204 has a gate connected to the output terminal 402 and a drain connected to the node N1.

Note that, although not illustrated, the NMOS transistors 201 to 204 each have a back gate connected to VSS or a lower potential than its source potential, while the PMOS transistor 101 has a back gate connected to VDD or a higher potential than its source potential.

Next, an operation of the input circuit having hysteresis characteristics according to the third embodiment is described.

If an input voltage VIN shifts from Low to High, a voltage of the output terminal 402 remains Low until the input voltage falls below a threshold of the entire circuit. The NMOS transistors 203 and 204 are accordingly turned OFF. When the input voltage thereafter exceeds a threshold of the circuit formed of the PMOS transistor 101 and the NMOS transistor 201, the node N1 shifts to Low and the output terminal 402 shifts from Low to High. In other words, the threshold of the entire circuit is determined by the threshold of the circuit formed of the PMOS transistor 101 and the NMOS transistor 201, the value of which is determined by a ratio of ON-state resistances between the PMOS transistor 101 and the NMOS transistor 201.

If the input voltage shifts from High to Low, the voltage of the output terminal 402 remains High until the input voltage falls below the threshold of the entire circuit. The NMOS transistors 203 and 204 are accordingly turned ON. Therefore, as compared with the shift of the input from Low to High, the ON-state resistance of the NMOS transistor 201 is small because of the NMOS transistors 202 and 204. This way, the threshold of the entire circuit increases to provide hysteresis to the input circuit.

Here, taking no account of the NMOS transistor 204, consider the power supply voltage dependence of the configuration of the circuit diagram of FIG. 3 including the NMOS transistors 201 to 203, the PMOS transistor 101, and the inverter 501. If the input voltage approaches the threshold voltage from High at a low power supply voltage, the NMOS transistors 201 and 202 are each biased in the weak inversion region. The ON-state resistances of the NMOS transistors 201 and 202 at this time are larger than those at a high power supply voltage, where the NMOS transistors 201 and 202 each operate in the strong inversion region with the input voltage being around the threshold voltage. Therefore, under the condition of low power supply voltage, a small hysteresis voltage is obtained.

Next, taking no account of the NMOS transistors 202 and 203, consider the power supply voltage dependence of the configuration of the circuit diagram of FIG. 3 including the NMOS transistors 201 and 204, the PMOS transistor 101, and the inverter 501. As described above, under the condition of low power supply voltage, when the input voltage approaches the circuit threshold voltage from High, the NMOS transistors 201 and 204 are each biased in the weak inversion region to have a larger ON-state resistance than that under the condition of high power supply voltage. On this occasion, a gate-source voltage of the NMOS transistor 204 remains equal to the power supply voltage until the output terminal 402 is inverted to Low. Therefore, the ON-state resistance of the NMOS transistor 204 is hardly dependent on the power supply voltage as long as the power supply voltage is equal to or higher than the transistor threshold of the NMOS transistor 204. Further, as the power supply voltage becomes lower, an influence of current drivability of the NMOS transistor 204 becomes larger to reduce the ON-state resistances of the NMOS transistors. Consequently, under the condition of low power supply voltage, a large hysteresis voltage is obtained.

The input circuit according to the third embodiment is provided with two circuits, one of which is formed of the NMOS transistors 201 and 204 and the inverter 501 and enabled under the condition of low power supply voltage to keep a large hysteresis voltage, and the other of which is formed of the NMOS transistors 201 to 203 and the inverter 501 and enabled under the condition of high power supply voltage to keep a large hysteresis voltage as well. This way, the power supply voltage dependence of the hysteresis voltage may be suppressed. There is therefore no need to increase the current drivability of the NMOS transistor 202 at the high power supply voltage, so as to allow the NMOS transistor 202 with low current drivability. Besides, current consumption during switching may be reduced as well. Further, it is possible to further reduce a ratio of the current drivability of the NMOS transistor 202 to that of the PMOS transistor 101, and hence the response speed for input from Low to High is prevented from reducing at the low power supply voltage.

As described above, the input circuit having hysteresis characteristics of the third embodiment is capable of operating in a wide range of power supply voltage conditions while suppressing the power supply voltage dependence of the hysteresis voltage and the response speed. Besides, current consumption during switching may be reduced without increasing a circuit scale.

### Fourth Embodiment

FIG. 4 is an input circuit having hysteresis characteristics according to a fourth embodiment of the present invention.

The input circuit having hysteresis characteristics according to the fourth embodiment includes NMOS transistors 201 to 204, a PMOS transistor 101, an inverter 501, a first power source 301 (hereinafter referred to as VDD), a second power source 302 (hereinafter referred to as VSS), the voltage of which is lower than that of the first power source 301, an input terminal 401, and an output terminal 402. The fourth embodiment is different from the third embodiment in the following points. The NMOS transistor 202 has a drain connected to a node N1 and a source connected to a node N3. The NMOS transistor 203 as the interrupting means has a drain connected to the node N3 and a source connected to VSS.

Next, an operation of the input circuit having hysteresis characteristics according to the fourth embodiment is described.

As compared with the third embodiment, the fourth embodiment has a configuration in which the NMOS transistor 202 and the NMOS transistor 203 switch places with each other. Also in this case, the input circuit operates in the same manner as in the third embodiment to obtain the same effects.

Therefore, the input circuit having hysteresis characteristics according to the fourth embodiment is capable of operating in a wide range of power supply voltage conditions while suppressing the power supply voltage dependence of the hysteresis voltage and the response speed. Besides, current consumption during switching may be reduced without increasing a circuit scale.

### Fifth Embodiment

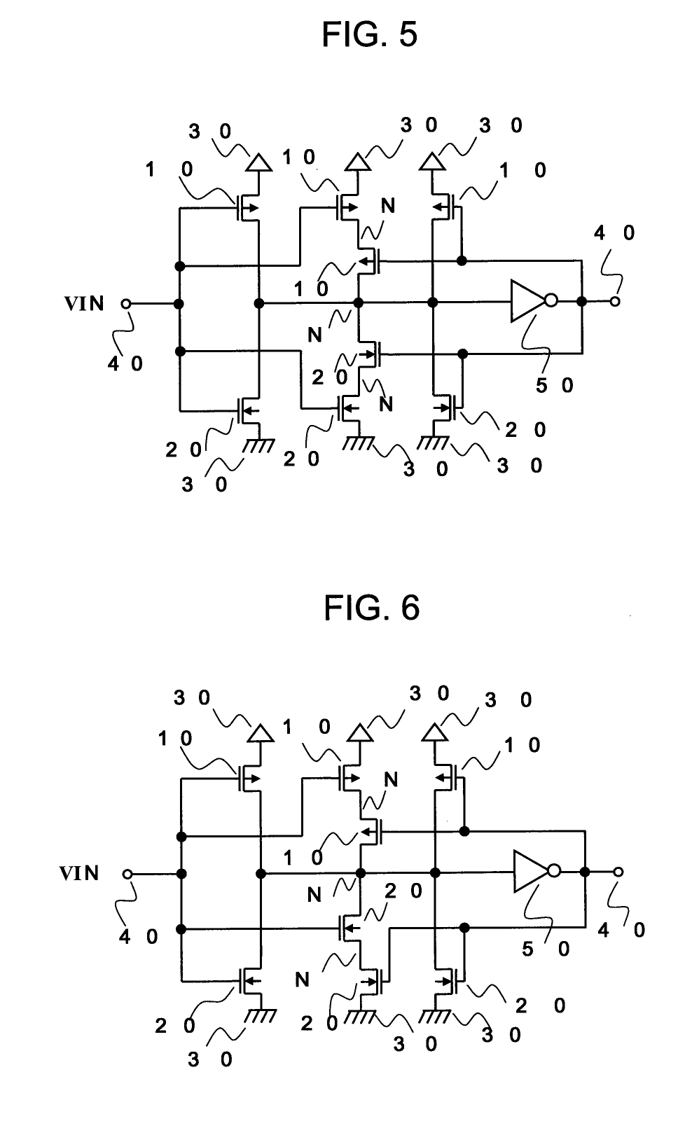

FIG. 5 is an input circuit having hysteresis characteristics according to a fifth embodiment of the present invention.

The input circuit having hysteresis characteristics according to the fifth embodiment includes NMOS transistors 201 to 204, PMOS transistors 101 to 104, an inverter 501, a first power source 301 (hereinafter referred to as VDD), a second power source 302 (hereinafter referred to as VSS), the voltage of which is lower than that of the first power source 301, an input terminal 401, and an output terminal 402.

The NMOS transistors 201, 202, and 204 each have a source connected to VSS, while the PMOS transistors 101, 102, and 104 each have a source connected to VDD. The PMOS transistor 101 and the NMOS transistor 201 each have a gate connected to the input terminal 401 and a drain connected to a node N1. The inverter 501 has an input connected to the node N1 and an output connected to the output terminal 402. The NMOS transistor 202 has a gate connected to the input terminal 401 and a drain connected to a node N3. The NMOS transistor 203 has a gate connected to the output terminal 402, a source connected to the node N3, and a drain connected to the node N1. The NMOS transistor 204 has a gate connected to the output terminal 402 and a drain connected to the node N1. The PMOS transistor 102 has a gate connected to the input terminal 401 and a drain connected to the node N2. The PMOS transistor 103 has a gate connected to the output terminal 402, a source connected to the node N2, and a drain connected to the node N1. The PMOS transistor 104 has a gate connected to the output terminal 402 and a drain connected to the node N1.

Note that, although not illustrated, the NMOS transistors 201 to 204 each have a back gate connected to VSS or a lower potential than its source potential, while the PMOS transistors 101 to 104 each have a back gate connected to VDD or a higher potential than its source potential.

Next, an operation of the input circuit having hysteresis characteristics according to the fifth embodiment is described.

The input circuit having hysteresis characteristics according to the fifth embodiment has a circuit configuration obtained by a combination of the first embodiment and the third embodiment. Therefore, the input circuit has two kinds of configuration, one of which is aimed at obtaining a small hysteresis voltage at a low power supply voltage (formed of the PMOS transistors 101 to 103 or the NMOS transistors 201 to 203, and the inverter 501) and the other of which is aimed at obtaining a large hysteresis voltage at the low power supply voltage (formed of the PMOS transistors 101 and 104 or the NMOS transistors 201 and 204, and the inverter 501).

The input circuit according to the fifth embodiment is provided with two circuits, one of which is formed of the PMOS transistors 101 and 104 or the NMOS transistors 201 and 204 and the inverter 501 and enabled under the condition of low power supply voltage to keep a large hysteresis voltage, and the other of which is formed of the PMOS transistors 101 to 103 or the NMOS transistors 201 to 203 and the inverter 501 and enabled under the condition of high power supply voltage to keep a large hysteresis voltage as well. This way, the power supply voltage dependence of the hysteresis voltage may be suppressed. There is therefore no need to increase the current drivability of the PMOS transistor 102 and the NMOS transistor 202 at the high power supply voltage, so as to allow the PMOS transistor 102 and the NMOS transistor 202 with low current drivability. Besides, current consumption during switching may be reduced as well. Further, it is possible to further reduce a ratio of the current drivability of the PMOS transistor 102 to that of the NMOS transistor 201 and to further reduce a ratio of the current drivability of the NMOS transistor 202 to that of the PMOS transistor 101, and hence the response speed for input from Low to High is prevented from reducing at the low power supply voltage. With this configuration, a large hysteresis voltage may be obtained.

As described above, the input circuit having hysteresis characteristics of the fifth embodiment is capable of operating in a wide range of power supply voltage conditions while suppressing the power supply voltage dependence of the hysteresis voltage and the response speed. Besides, current consumption during switching may be reduced without increasing a circuit scale, and a large hysteresis voltage may be obtained.

### Sixth Embodiment

FIG. 6 is an input circuit having hysteresis characteristics according to a sixth embodiment of the present invention.

The input circuit having hysteresis characteristics according to the sixth embodiment includes NMOS transistors 201 to 204, PMOS transistors 101 to 104, an inverter 501, a first power source 301 (hereinafter referred to as VDD), a second power source 302 (hereinafter referred to as VSS), the voltage of which is lower than that of the first power source 301, an input terminal 401, and an output terminal 402. The sixth embodiment is different from the fifth embodiment in the following points. The NMOS transistor 202 has a drain connected to a node N1 and a source connected to a node N3. The NMOS transistor 203 has a drain connected to the node N3 and a source connected to VSS.

Next, an operation of the input circuit having hysteresis characteristics according to the sixth embodiment is described.

As compared with the fifth embodiment, the sixth embodiment has a configuration in which the NMOS transistor 202 and the NMOS transistor 203 switch places with each other. Also in this case, the input circuit operates in the same manner as in the fifth embodiment to obtain the same effects.

As described above, the input circuit having hysteresis characteristics according to the sixth embodiment is capable of operating in a wide range of power supply voltage conditions while suppressing the power supply voltage dependence of the hysteresis voltage and the response speed. Besides, current consumption during switching may be reduced without increasing a circuit scale, and a large hysteresis voltage may be obtained.

### Seventh Embodiment

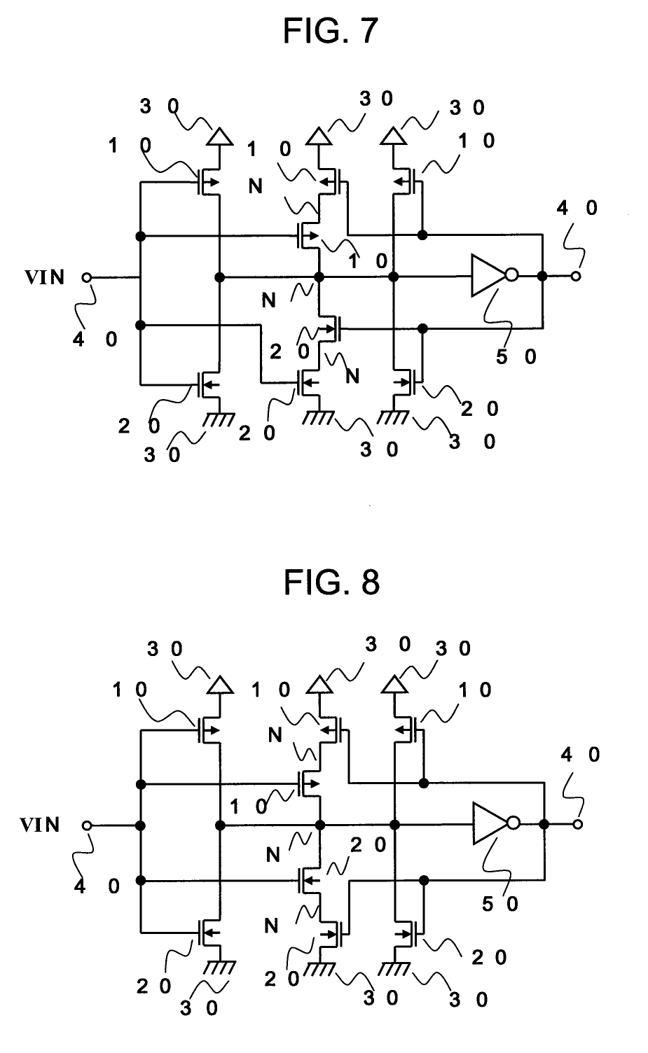

FIG. 7 is an input circuit having hysteresis characteristics according to a seventh embodiment of the present invention.

The input circuit having hysteresis characteristics according to the seventh embodiment includes NMOS transistors 201 to 204, PMOS transistors 101 to 104, an inverter 501, a first power source 301 (hereinafter referred to as VDD), a second power source 302 (hereinafter referred to as VSS), the voltage of which is lower than that of the first power source 301, an input terminal 401, and an output terminal 402. The seventh embodiment is different from the fifth embodiment in the following points. The PMOS transistor 102 has a drain connected to a node N1 and a source connected to a node N2. The PMOS transistor 103 has a drain connected to the node N2 and a source connected to VDD.

Next, an operation of the input circuit having hysteresis characteristics according to the seventh embodiment is described.

As compared with the fifth embodiment, the seventh embodiment has a configuration in which the PMOS transistor 102 and the PMOS transistor 103 switch places with each other. Also in this case, the input circuit operates in the same manner as in the fifth embodiment to obtain the same effects.

As described above, the input circuit having hysteresis characteristics according to the seventh embodiment is capable of operating in a wide range of power supply voltage conditions while suppressing the power supply voltage dependence of the hysteresis voltage and the response speed. Besides, current consumption during switching may be reduced without increasing a circuit scale, and a large hysteresis voltage may be obtained.

### Eighth Embodiment

FIG. 8 is an input circuit having hysteresis characteristics according to an eighth embodiment of the present invention.

The input circuit having hysteresis characteristics according to the eighth embodiment includes NMOS transistors 201 to 204, PMOS transistors 101 to 104, an inverter 501, a first power source 301 (hereinafter referred to as VDD), a second power source 302 (hereinafter referred to as VSS), the voltage of which is lower than that of the first power source 301, an input terminal 401, and an output terminal 402. The eighth embodiment is different from the fifth embodiment in the following points. The PMOS transistor 102 has a drain connected to a node N1 and a source connected to a node N2. The PMOS transistor 103 has a drain connected to the node N2 and a source connected to VDD. The NMOS transistor 202 has a drain connected to the node N1 and a source connected to a node N3. The NMOS transistor 203 has a drain connected to the node N3 and a source connected to VSS.

Next, an operation of the input circuit having hysteresis characteristics according to the eighth embodiment is described.

As compared with the fifth embodiment, the eighth embodiment has a configuration in which the PMOS transistor 102 and the PMOS transistor 103 switch places with each other and the NMOS transistor 202 and the NMOS transistor 203 switch places with each other. Also in this case, the input circuit operates in the same manner as in the fifth embodiment to obtain the same effects.

As described above, the input circuit having hysteresis characteristics according to the eighth embodiment is capable of operating in a wide range of power supply voltage conditions while suppressing the power supply voltage dependence of the hysteresis voltage and the response speed. Besides, current consumption during switching may be reduced without increasing a circuit scale, and a large hysteresis voltage may be obtained.

### Ninth Embodiment

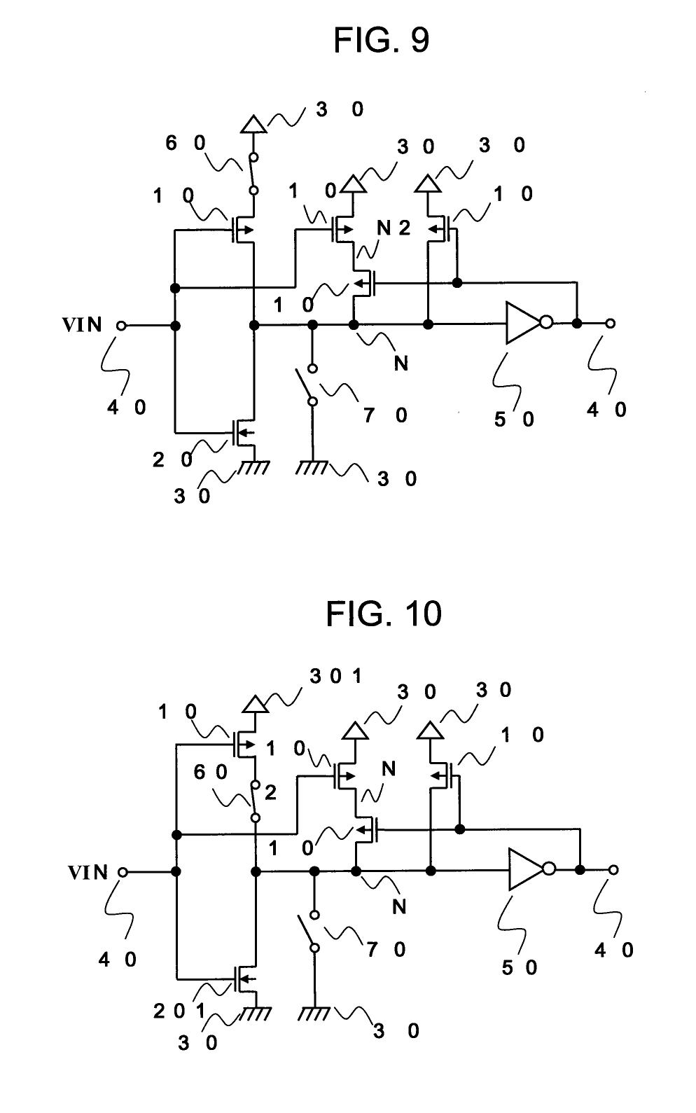

FIG. 9 is an input circuit having hysteresis characteristics according to a ninth embodiment of the present invention.

The input circuit having hysteresis characteristics according to the ninth embodiment includes PMOS transistors 101 to 104, an NMOS transistor 201, an inverter 501, a first power source 301 (hereinafter referred to as VDD), a second power source 302 (hereinafter referred to as VSS), the voltage of which is lower than that of the first power source 301, an input terminal 401, an output terminal 402, and switching elements 601 and 701. The difference from the first embodiment resides in that the switching element 601 is added between the PMOS transistor 101 and VDD and that the switching element 701 is added between the node N1 and VSS.

Next, an operation of the input circuit having hysteresis characteristics according to the ninth embodiment is described.

The ninth embodiment is achieved by adding the switching elements 601 and 701 to the circuit of the first embodiment. This configuration enables control on the switching element using an enable signal input thereto so as to electrically interrupt the switching element if the enable signal is Enable while electrically connect the switching element if the enable signal is Disable. The switching elements have no influence on operations of other components. Therefore, the ninth embodiment, being comparable to the first embodiment, can obtain the effects equivalent to those of the first embodiment. Further, although not illustrated, the switching element may be used in the second to eighth embodiments to obtain the same effects.

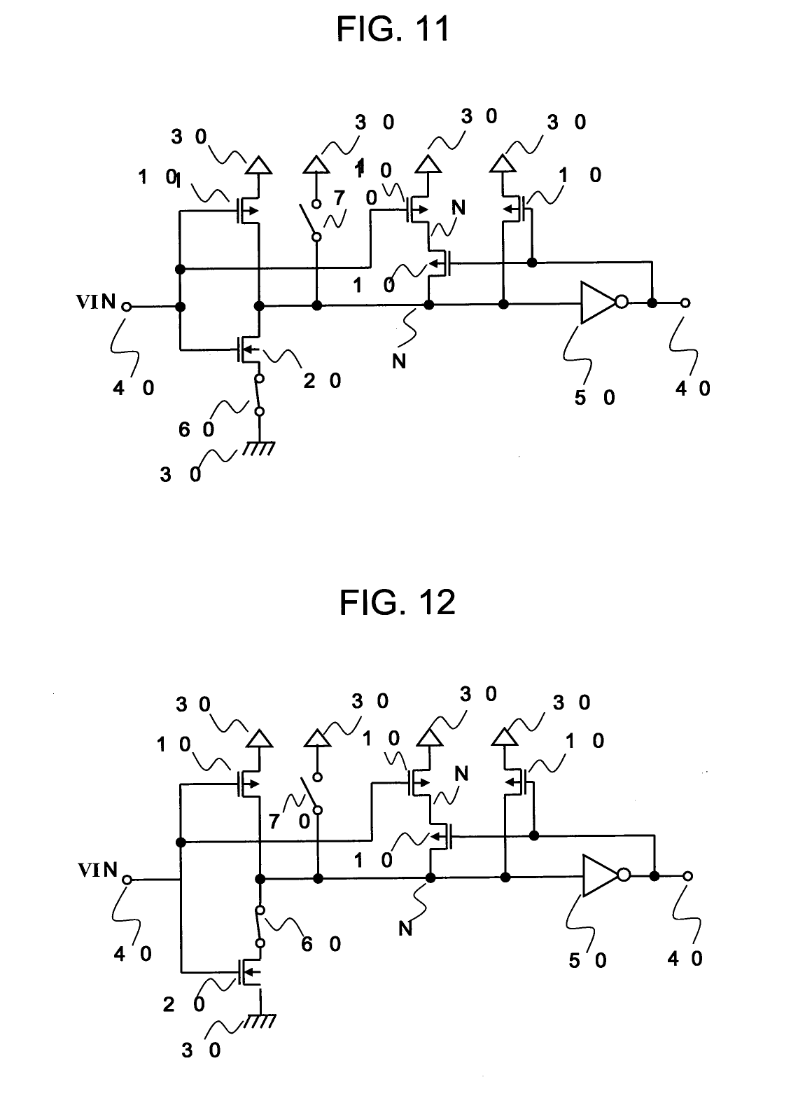

FIGS. 10 to 12 are circuit diagrams each illustrating another example of the ninth embodiment, in which switching elements 602, 603, 604, and 702 are interposed in different positions. Such modification on the positions where the switching elements are interposed can also provide the same effects. Further, although not illustrated, the switching element may be used in the second to eighth embodiments to obtain the same effects.

As described above, the input circuit having hysteresis characteristics according to the ninth embodiment is capable of operating in a wide range of power supply voltage conditions while suppressing the power supply voltage dependence of the hysteresis voltage and the response speed. Besides, current consumption during switching may be reduced without increasing a circuit scale, and a large hysteresis voltage may be obtained.

### Tenth Embodiment

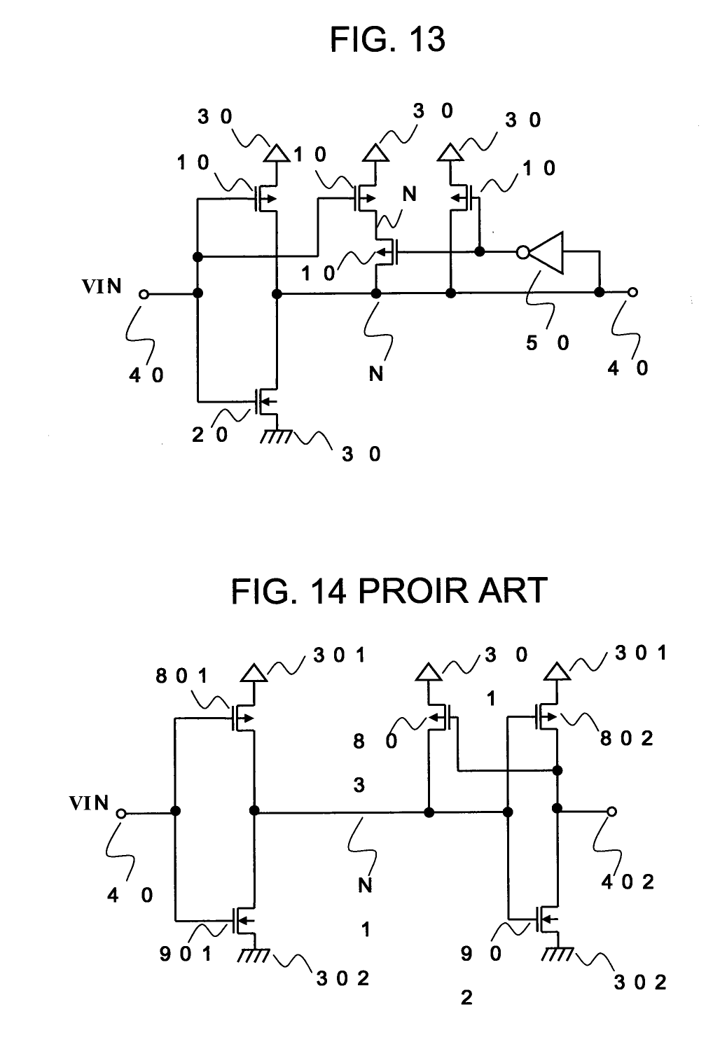

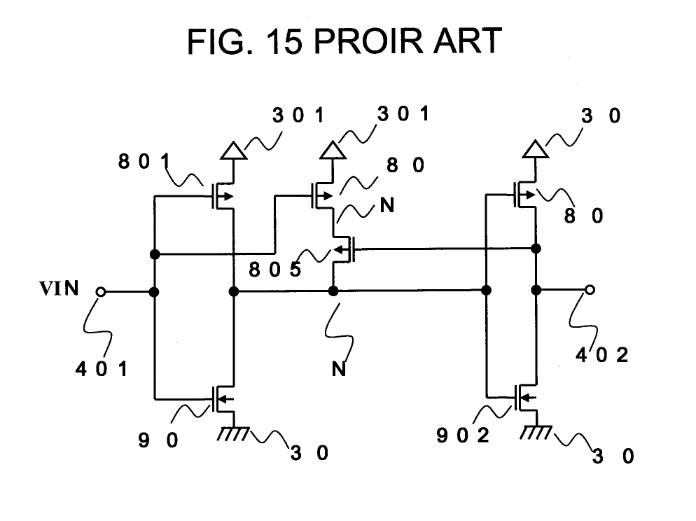

FIG. 13 is an input circuit having hysteresis characteristics according to a tenth embodiment of the present invention.

The input circuit having hysteresis characteristics according to the tenth embodiment includes PMOS transistors 101 to 104, an NMOS transistor 201, an inverter 501, a first power source 301 (hereinafter referred to as VDD), a second power source 302 (hereinafter referred to as VSS), the voltage of which is lower than that of the first power source 301, an input terminal 401, and an output terminal 402. The tenth embodiment is different from the first embodiment in the following point. Where to connect the inverter 501 is changed such that the output terminal 402 is connected to the node N1 to thereby invert the logic of the output terminal 402.

Next, an operation of the input circuit having hysteresis characteristics according to the tenth embodiment is described.

As compared with the first embodiment, the tenth embodiment has a configuration in which the output terminal 402 is connected to the node N1. Accordingly, the difference therefrom is only the change in logic of the output terminal 402, and hence other operations are not affected. Therefore, the input circuit has the output logic inverted from that of the first embodiment, but has the same effects as in the first embodiment. Further, although not illustrated, such configuration may be used in the second to ninth embodiments to obtain the same effects.

As described above, the input circuit having hysteresis characteristics according to the tenth embodiment is capable of operating in a wide range of power supply voltage conditions while suppressing the power supply voltage dependence of the hysteresis voltage and the response speed.

What is claimed is:

1. An input circuit, comprising:
an input terminal for receiving an input voltage;
an output terminal for outputting an output signal to be determined based on the input voltage;
a first PMOS transistor including a gate to which the input voltage is input, for charging a first node when the input voltage is Low;
a first NMOS transistor including a gate to which the input voltage is input, for discharging the first node when the input voltage is High;
a second PMOS transistor including a gate to which the input voltage is input, for charging the first node when the input voltage is Low;
first interrupting means for interrupting a charge path of the second PMOS transistor to the first node when a voltage of the first node is Low; and
a third PMOS transistor for charging the first node when the voltage of the first node is High.

2. An input circuit according to claim 1, wherein the first interrupting means comprises a PMOS transistor.

3. An input circuit according to claim 1, further comprising an inversion circuit between the first node and the output terminal,
wherein the output signal comprises an output signal of the inversion circuit.

4. An input circuit, comprising:
an input terminal for receiving an input voltage;
an output terminal for outputting an output signal to be determined based on the input voltage;
a first PMOS transistor including a gate to which the input voltage is input, for charging a first node when the input voltage is Low;
a first NMOS transistor including a gate to which the input voltage is input, for discharging the first node when the input voltage is High;
a second NMOS transistor including a gate to which the input voltage is input, for discharging the first node when the input voltage is High;
second interrupting means for interrupting a discharge path of the second NMOS transistor from the first node when a voltage of the first node is High; and
a third NMOS transistor for discharging the first node when the voltage of the first node is Low.

5. An input circuit according to claim 4, wherein the second interrupting means comprises an NMOS transistor.

6. An input circuit according to claim 4, further comprising an inversion circuit between the first node and the output terminal,
wherein the output signal comprises an output signal of the inversion circuit.

7. An input circuit, comprising:
an input terminal for receiving an input voltage;
an output terminal for outputting an output signal to be determined by the input voltage;
a first PMOS transistor including a gate to which the input voltage is input, for charging a first node when the input voltage is Low;
a first NMOS transistor including a gate to which the input voltage is input, for discharging the first node when the input voltage is High;
a second PMOS transistor including a gate to which the input voltage is input, for charging the first node when the input voltage is Low;
first interrupting means for interrupting a charge path of the second PMOS transistor to the first node when a voltage of the first node is Low;
a third PMOS transistor for charging the first node when the voltage of the first node is High;
a second NMOS transistor including a gate to which the input voltage is input, for discharging the first node when the input voltage is High;
second interrupting means for interrupting a discharge path of the second NMOS transistor from the first node when the voltage of the first node is High; and
a third NMOS transistor for discharging the first node when the voltage of the first node is Low.

8. An input circuit according to claim 7,
wherein the first interrupting means comprises a PMOS transistor, and
wherein the second interrupting means comprises an NMOS transistor.

9. An input circuit according to claim 7, further comprising an inversion circuit between the first node and the output terminal,
wherein the output signal comprises an output signal of the inversion circuit.
